(19) United States
(12) Patent Application Publication
(10) Pub. No.: US 2015/0329989 A1
(43) Pub. Date: Nov. 19, 2015

(54) MULTI-CRYSTAL DIAMOND BODY

(71) Applicant: DIAMOND INNOVATIONS, INC., Worthington, OH (US)

(72) Inventors: Valeriy V KONOVALOV, Lewis Center, OH (US); John LUCEK, Powell, OH (US)

(21) Appl. No.: 14/652,937

(22) PCT Filed: Dec. 31, 2012
(86) PCT No.: PCT/US2012/072319

§ 371 Date: Jun. 17, 2015

(51) Int. Cl. C30B 28/14; C30B 25/12; C30B 25/04; C30B 30/00; C30B 25/22; C30B 29/04; C30B 29/68; C30B 25/10; C30B 25/20

(52) U.S. Cl. CPC C30B 28/14; C30B 25/105; C30B 25/12; C30B 25/04; C30B 25/20; C30B 25/22; C30B 29/04; C30B 29/68; C30B 30/00

(57) ABSTRACT

A synthetic diamond body and method of making the synthetic diamond body are provided. The synthetic diamond body having a low stress and free of cracks may comprise a first single crystal partial volume having the first crystallographic orientation and a one or more of other single crystal partial volumes, wherein the first partial volume occupies less than about 100% of the total volume of synthetic diamond wafer, and each other single crystal partial volume has its own crystallographic orientation; and each other single crystal partial volume comprises a plurality of single crystal volumes all having about the same crystallographic orientation, wherein the crystallographic orientation of each partial volume is fixed against the first crystallographic orientation by a geometrical operation.

### BACKGROUND OF THE INVENTION

The present invention relates to a multi-crystal diamond body and a method of making such diamond body, more specifically, to a synthetic multi-crystal diamond body grown by chemical vapor deposition (CVD) or other techniques. The diamond body includes a limited number of single crystal regions having two or more crystallographic orientations. The orientations are not random and related to each other by a geometrical operation. The diamond growth conditions for the formation of specific crystallographic orientations in the multi-crystal diamond body produce high quality, crack free diamond substrates suitable for optical, electronic, semiconductor, tooling, and many other diamond applications.

Diamond possesses a number of unique physical properties, such as extreme hardness, extreme thermal conductivity, high carrier mobility, transparency over a wide range of electromagnetic wavelengths, long spin-relaxation times, etc., making it an excellent material for many applications. Diamond may be grown in different crystalline forms. One extreme case may be a single (or mono-) crystal. Another extreme case, which is the most common and represents the majority of conventional polycrystalline diamonds, may be a poly-crystal, including a plurality of small single crystals (often called grains) randomly oriented with respect to each other. Grain sizes in conventional polycrystalline diamond may range from about 0.1 to about 1 μm (fine grains), to about 1 to about 10 μm (medium grains), and to about 10 to about 100 μm (large grains). The numerous grain boundaries in polycrystalline diamond are responsible for significant differences between physical properties of single crystal and polycrystalline diamond. For example, the presence of grain boundaries reduces diamond's thermal conductivity, electron/hole mobility, and transparency to radiation. As result, many important properties of conventional polycrystalline diamond are inferior to a single crystal diamond. Significant reduction of the number of grain boundaries may improve the quality of polycrystalline material making it more close to a single crystal material.

One specific form of polycrystalline material, including diamond, is a material where twins are present. Twins are a highly oriented association of two or more individual single crystals of the same phase in which the mutual orientation is not random, but related by a geometrical operation. Geometric operations may be those related to crystal symmetry and include rotation, reflection, and inversion, but not, generally, those related to translation. The inclination between twinned crystals is typically large, usually exceeding about 10°. It may be assumed by the skilled in the art person that a single crystal diamond is an untwinned crystal.

In many applications, the full potential of diamond material may be realized only through the use of either single crystal diamond or a polycrystalline diamond having properties very close to single crystal diamond. In addition, many diamond applications may require fabrication of high quality diamond components larger than about 1 cm diameter in several dimensions. However, natural single crystal diamonds larger than about 1 cm are extremely expensive. Production of synthetic single crystal diamonds by high pressure high temperature (HPHT) processes is also limited to about the same size of about 1 cm. One of the most common shapes of diamond for many applications (for example for electronic, optical, and sensor applications) is a diamond wafer representing a thin and flat slice of diamond material. As used herein, the term wafer refers to a three dimensional body without restriction. Low pressure diamond growth from a vapor phase (or vapor deposition) may produce synthetic diamond wafers up to about 20 to about 30 cm diameter and potentially larger. It has been demonstrated that the production cost of synthetic diamond by vapor deposition may drop significantly with increase of diamond size.

In the vapor deposition method, diamond grows from highly reactive gas phase carbon precursors, created by the activation of feed gases. The activation may be achieved in different ways which define different vapor deposition methods. For example, activation may be achieved by using plasma, high temperature, laser, ionizing radiation, or, in general, using any method resulting in appearance of relevant diamond growth carbon precursors near the growth surface. Plasma vapor deposition techniques may include microwave, direct current (DC), radio frequency (RF), arc jet, flame torch, glow discharge, and other techniques creating plasmas. Sometimes different vapor deposition techniques are defined as chemical vapor deposition (CVD) or physical vapor deposition (PVD). For example, some of abovementioned vapor deposition techniques are often defined as hot filament CVD, plasma CVD/plasma assisted CVD, microwave plasma CVD, microwave plasma assisted CVD, DC plasma CVD, etc. Existing CVD/PVD techniques are well suited to grow both polycrystalline and single crystal diamond material.

Single crystal diamond bodies may be produced by vapor deposition homoepitaxial diamond growth wherein the grown crystalline overlayer is the same material and the same crystalline orientation as the crystalline substrate (which may be also called seed). Homoepitaxial diamond growth of large size single crystal diamonds requires expensive large size natural or HPHT single crystal diamond substrates. An alternative approach to grow large size single crystal diamond is a mosaic method, wherein relatively smaller single crystal substrates, having the same crystal orientation, form a joint planar growth surface upon which a single crystal diamond overlayer is grown bonding smaller substrates together. Previously, mosaic CVD single crystal diamond s growth methods have been described for the growth of homoepitaxial single crystal diamond overlayers, and physical properties of such overlayers. However, practical attempts to fabricate large size single crystal diamond wafers from single crystal diamond overlayers grown over a mosaic substrate resulted in poor quality products, having cracks and uncontrolled polycrystalline diamond inclusions. It has been suggested previously that the high stress in diamond overlayers, leading to cracking, is the result of formation of polycrystalline inclusions in the diamond overlayer and between the initial diamond seed crystals. As a result, all growth particles such as twins, polycrystalline regions, abnormal particles, etc. were considered as highly unwanted defects which had to be completely eliminated by the proper growth conditions providing pure single crystal growth.

Therefore, as can be seen, there is a need for a new type diamond material with properties close to a single crystal diamond and which is large enough or otherwise suitable for commercial and scientific applications. The present invention is a new multi-crystal diamond body with a limited number of highly oriented single crystal regions, and a method of making such multi-crystal diamond body. The properties of this multi-crystal diamond body are very close to those of single crystal diamond.

### SUMMARY OF THE INVENTION

In one embodiment of the present invention, a multi-crystal diamond body comprises a limited number of single crystal regions having two or more, crystallographic orientations significantly different from each other, but related to each other by a geometrical operation.

In another embodiment, a synthetic multi-crystal diamond body comprises a first single crystal partial volume and one or more of other single crystal partial volumes, wherein the first partial volume occupies less than about 100% of the total synthetic diamond body volume, and has the first crystallographic orientation; and each other single crystal partial volume comprises a plurality of single crystals volumes all having about the same crystallographic orientation; wherein the crystallographic orientation of each other partial volume is fixed against the first crystallographic orientation.

In still another embodiment, a method of making multi-crystal diamond body includes the steps of growing a first diamond layer over a first growth surface comprising surfaces of a plurality of single crystal diamond seeds on a substrate in a diamond deposition reactor; removing the substrate with a plurality of seeds and overgrown first diamond layer from the reactor; separating the plurality of seeds with overgrown diamond layer from the substrate; turning over the plurality of seeds with the first overgrown diamond layer, to provide a new diamond growth surface of a plurality of seeds, wherein the second diamond growth surface is different from the first grown diamond layer; growing a second diamond layer on the new diamond growth surface the plurality of single crystal diamond seed in a diamond deposition reactor.

In still another embodiment, a diamond wafer is made from the multi-crystal diamond body by separating the first and second grown diamond layers from the first and second growth surfaces.

In still another embodiment, a method of making synthetic multi-crystal diamond body may include growing a first diamond layer over a growth surface of a plurality of single crystal diamond seeds on a substrate in a diamond deposition reactor; removing the substrate with a plurality of seeds and overgrown first diamond layer from the reactor; separating the plurality of seeds with first overgrown diamond layer from the substrate; turning over the plurality of seeds with the first overgrown diamond layer, thus making a second diamond growth surface of a plurality of seeds, wherein a new diamond growth surface is different from the first grown diamond layer; growing a second diamond layer on the second diamond growth surface comprising the plurality of single crystal diamond seeds in a diamond deposition reactor; growing a third diamond layer on the first diamond growth surface, which is different from the second diamond layer; growing a fourth diamond layer on the second diamond growth surface, which is different from the third diamond layer, thus making a multilayer diamond seed body; alternating growth on the different sides of multilayer diamond seed body, such as each new consecutive diamond growth surface is different from the previous grown diamond layer.

In still another embodiment, a diamond wafer is made by separating the first, second, and any subsequently grown diamond layers from the first, second, or subsequent growth surfaces. In still another embodiment, a method of making synthetic multi-crystal diamond wafer may comprise growing a first diamond layer over a growth surface of a plurality of single crystal diamond seeds on a substrate in a diamond deposition reactor; removing the substrate with a plurality of seeds and overgrown first diamond layer from the reactor; separating the plurality of seeds and the substrate from the overgrown diamond layer: thus producing new growth surfaces without the original seed crystals; growing a second diamond layer on the new growth surfaces thus created.

### BRIEF DESCRIPTION OF THE DRAWINGS

The foregoing summary, as well as the following detailed description of the embodiments, may be better understood when read in conjunction with the appended drawings. It should be understood that the embodiments depicted are not limited to the precise arrangements and instrumentalities shown.

FIG. 1 shows a schematic surface view of an exemplary embodiment of a diamond body including a first single crystal partial volume with one crystallographic orientation and the second partial volume, which comprises a plurality of single crystals all having the same second crystallographic orientation;

FIG. 2 shows a schematic surface view of an exemplary embodiment of a diamond body including the first single crystal partial volume with one crystallographic orientation; the second partial volume, comprising a plurality of single crystals all having the same second crystallographic orientation; and a third partial volume, comprising a plurality of single crystals all having the same third crystallographic orientation;

FIG. 3a shows a side schematic view and a schematic flow diagram of a method of making a diamond body according to an exemplary embodiment by growing a two-layer CVD diamond-seed body;

FIG. 3b show a side schematic view and a continued schematic flow diagram of a method of making a diamond body according to an exemplary embodiment by growing a multilayer CVD diamond-seed body; and

FIG. 4 shows a side schematic view of a separation of multilayer CVD diamond-seed body along the separation planes into several CVD diamond bodies and a remaining CVD diamond-seed body.

FIG. 5 shows an inverse pole figure corresponding to the electron back scattering diffraction pattern of the exemplary multi-crystal diamond body.

### DETAILED DESCRIPTION

Exemplary embodiments provide a new type of polycrystalline diamond material, described as a “multi-crystal diamond” which has properties close to single crystal diamonds and diamond bodies or wafers made from this material. This multi-crystal diamond may have large lateral sizes over about 1 cm and may be used for making optical windows, electronic devices, sensors, heat sinks, and in many other diamond applications.

Exemplary embodiments provide a new type of multi-crystal diamond, in which different single crystal partial volumes have two or more consistent crystallographic orientations, that is, not randomly oriented. The two or more consistent crystallographic orientations are related to each other by a geometrical operation. This multi-crystal diamond may be fabricated using selected vapor deposition growth conditions, where the growth of randomly oriented poly-crystals is suppressed and where ordered polycrystalline inclusions may be predominantly present. This multi-crystal diamond may be less vulnerable to cracking and its properties may be superior to conventional polycrystalline diamond with randomly oriented grains. The multi-crystal diamond properties may be close to the properties of single crystal diamond.

One exemplary embodiment of current invention is the fabrication of multi-crystal diamond mosaic body using a plurality of single crystal diamond seed-plates having the same or very close crystalline orientations. Seed-plates may be single crystal diamond bodies. Deviation between the crystal orientations of different seed-plates should be less than about 5° and seed-plates should be separated from each other as little as possible (less than about 100 μm for example). Seed-plates may be made from natural or synthetic single crystal diamond material. Synthetic diamond seed plates may be fabricated by HPHT, CVD, PVD, or by any other suitable techniques producing good quality synthetic single crystal diamond. Seed-plates, which may be produced by lapping or polishing, should be flat and have low surface roughness. Surface roughness may be less than about 10 μm, or less than about 0.1 μm, for example. Seed plates may have to be cleaned to remove surface contaminations, using standard diamond cleaning techniques. For example, solvent cleaning, hot acid cleaning, molten salt cleaning, high temperature treatment in hydrogen atmosphere, plasma etching, or any suitable surface cleaning technique.

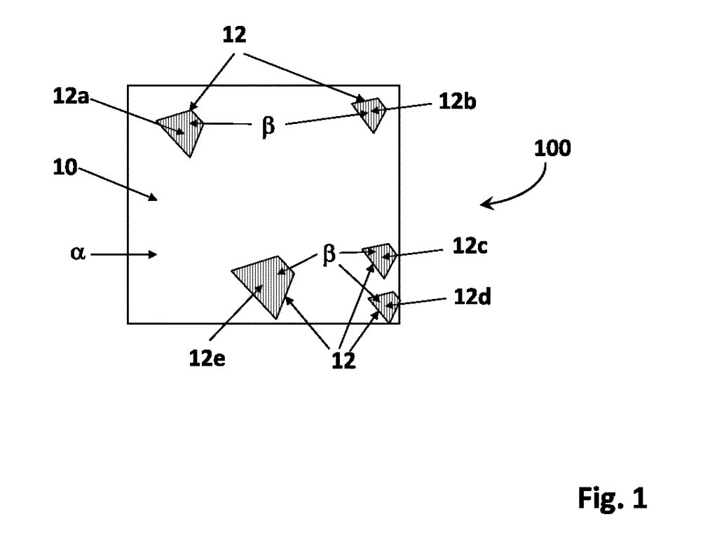

FIG. 1 shows a two dimensional representation (or a surface view) of a synthetic diamond wafer 100 which may include a first partial wafer area 10 and a second partial wafer area 12, representing corresponding first and second single crystal partial volumes of the wafer. The first partial area 10 may occupy less than about 100% of the total area of wafer 100. The first partial wafer area 10 may represent a single crystal having a first crystallographic orientation α. The second partial wafer area 12 may comprise a plurality of single crystal areas all having the same second crystallographic orientation β, which is significantly different from the first crystallographic orientation α. For example in FIG. 1, a plurality of single crystals with orientation β is represented by sub-partial areas 12a, 12b, 12c, 12d, and 12e, and a second partial area 12 is a sum of those sub-partial areas. In one exemplary embodiment, the difference between the first crystallographic orientation α and second crystallographic orientation β may be more than about 5°.

In another exemplary embodiment, the second crystallographic orientation β may be different from the first crystallographic orientation α by more than about 8°, for example. In further exemplary embodiment, the second crystallographic orientation β may be different from the first crystallographic orientation α by more than about 10° for example.

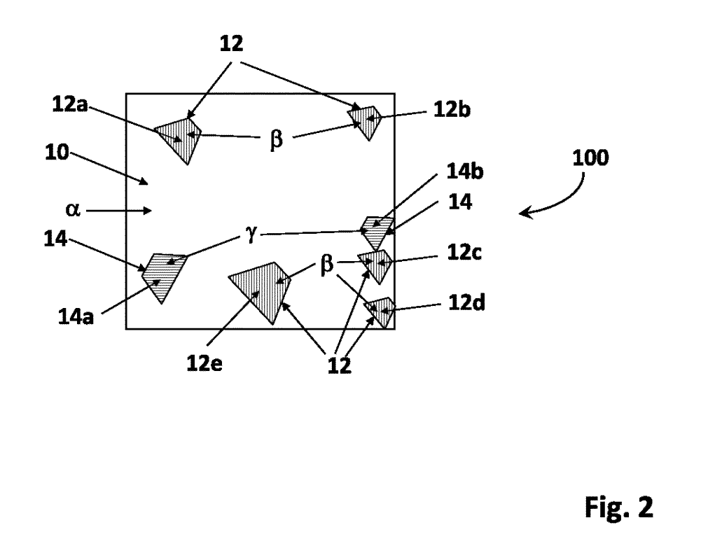

As shown in the two dimensional representation FIG. 2, a synthetic diamond wafer 100 may include a first partial wafer area 10, a second partial wafer area 12, and a third partial wafer area 14, representing corresponding first, second, and third single crystal partial volumes. The first partial area 10 may occupy less than about 100% of the total volume of wafer 100. The first partial wafer area 10 may represent a single crystal having a first crystallographic orientation α. The second partial wafer area 12 may comprise a plurality of single crystals all having the same second crystallographic orientation β. The third partial wafer area 14 may comprise a plurality of single crystals all having the same third crystallographic orientation γ. For example in FIG. 2, a plurality of single crystals with orientation γ may be represented by sub-partial areas 14a and 14b, and a third partial area 14 is a sum of those sub-partial areas. Crystallographic orientations α, β, and γ are significantly different from each other. In one exemplary embodiment, the difference between any two crystallographic orientation among α, β, and γ orientations may be more than about 5°.

In another exemplary embodiment, the difference between any two crystallographic orientation among α, β, and γ orientations may be more than about 8°, for example. In further another exemplary embodiment, the difference between any two crystallographic orientation among α, β, and γ orientations may be more than about 10° for example.

Still in FIG. 2, in one exemplary embodiment, the first single crystal partial wafer area 10 may have a first crystallographic orientation α. The second partial wafer area 12 may comprise a plurality of twinned single crystals all having the same second crystallographic orientation β. The third partial wafer volume 14 may comprise a plurality of twinned single crystals all having the same third crystallographic orientation γ. For example, the first single crystal partial wafer area may be the (100) crystalline plane, or another crystalline plane suitable for diamond growth, like (110), (111), (311), etc.

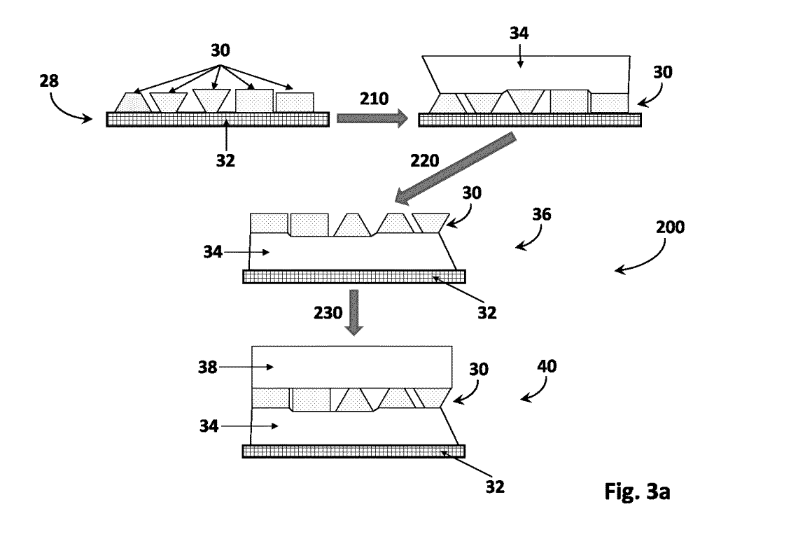

FIG. 3a and FIG. 3b show side schematic views and a schematic flow diagram 200 of a method of making a multi-crystal diamond wafer 100 according to an exemplary embodiment in which a plurality of seed-plates 30 may be placed on a support substrate 32 to make a seed assembly 28. The plurality of seed-plates 30 may be synthetic or natural single crystal diamond material, or it may be a multi-crystal diamond material disclosed in this invention. The method is not limited to a plurality of seed plates and may also be performed using a single seed plate. The seed assembly 28 may be placed in a sample holder (not shown) inside a CVD reactor. The seed crystal surfaces on which the diamond may be grown inside the vapor deposition reactor is a growth surface. The growth surface may face different suitable parts of deposition reactor, but typically it faces the part of reactor which provides the maximum deposition rate or the best deposition uniformity. For example, in plasma CVD reactor (microwave, DC, RF, etc.) the growth surface may face the plasma ball and in hot filament CVD reactor the growth surface may face the filament. The growth surfaces of the seed plates 28 may not deviate significantly (less than about 50 μm, or less than about 5 μm, for example) from the common imaginary plane passing through the growth surfaces of all seed plates. Support substrate 32 and sample holder may be made from materials which are stable at CVD growth conditions (high temperature, hydrogen atmosphere, etc.), such as, for example, Mo, W, Ta, Nb, Ti, or their alloys, or may include a broad variety of other materials suitable for deposition conditions. The surface of support substrate may be flat or may have recessed parts, which are made to accommodate seed-plates with different thickness. Finally, seed plates 28 may sit on the support plane freely or may be attached by, for example, a brazing method.

Additionally, before diamond growth, growth surfaces of seed plates 30 may be cleaned by using such techniques as mechanical cleaning, thermal cleaning, chemical cleaning, fusion cleaning, sonication cleaning, ion-beam cleaning, molecular-beam cleaning, plasma cleaning, etc. Specifically, plasma cleaning (or plasma etching) conditions may include different plasma chemical compositions created by using different feed gases (H₂, O₂, inert gases, halogen containing gases, sulfur containing gases, phosphorus containing gases, boron containing gases, for example), different gas pressure (from about 1 mTorr to about 760 Torr, for example), different substrate temperature (from about −200 ° C. to about 2000° C., for example), etc. Plasma cleaning may be done inside the plasma deposition reactor for diamond growth or in a separate reactor. Cleaning techniques may provide clean diamond surface without impurities, and also may reduce surface roughness and surface concentration of unwanted defects in the seed surfaces.

One example of diamond described in this invention is the CVD grown multi-crystal diamond body comprising of first single crystal partial volume, with a relatively large size and a limited number of other partial single crystal volumes comprising twinned single crystals. The stress between twinned crystals is lower than the stress between randomly oriented poly-crystals. Thus, exemplary embodiment of multi-crystal diamond may be grown without cracks, which are typical for diamond with randomly oriented poly-crystals.

The multi-crystal diamond wafer may be sliced/cut from multi-crystal diamond body described above. The wafer plane may be sliced/cut through one or more single crystal partial volumes, thus representing a cross-section of the body, and the single crystal partial areas on the wafer plane represent single crystal partial volumes which the plane crosses. Single crystal partial areas may have different crystallographic orientations, which can now be defined by Miller indices. For example the first single crystal partial area may have (100) orientation or it may have also one of the other main diamond orientations, like (110), (111), (311), etc.

FIG. 3a depicts a method 200 of making diamond wafer including the steps of providing a seed assembly 28, including a plurality of single crystal diamond seeds 30 on a substrate 32; placing the seed assembly 28 into a vapor deposition reactor, such as a chemical vapor deposition reactor, for example; growing a first diamond layer 34 over the growth surfaces of the plurality of seeds 30 in a step 210, bonding diamond seeds together and making a joined diamond layer-seed assembly body 36; removing the substrate 32 with the diamond layer-seed assembly body 36 from the vapor deposition reactor; separating the diamond layer-seed assembly body 36 from the substrate 32; reorienting the diamond layer-seed assembly body 36 and placing it on a substrate 32, replacing the reoriented assembly into the deposition reactor in a step 230, in a such way, that the new diamond growth surface will be a different side of the plurality of single crystal diamond seeds 30; and growing a second diamond layer 38 on the new growth surface representing a different side of the plurality of single crystal diamond seed in a step 230, thus making a diamond multilayer-seed assembly body 40. In step 230, the individual growth surfaces of the seed plates 28 may not deviate significantly (less than about 50 μm, or less than about 5 μm, for example) from the common imaginary plane passing through the growth surfaces of all seed plates.

As shown in FIG. 3b, above mentioned steps 220 and 230 may be repeated as steps 240 and 250, potentially many times, but in each new step, the diamond multilayer-seed assembly body 40 is turned over and placed back on the sample holder inside the diamond deposition reactor in a way that the new diamond growth surface will be opposite to the previous diamond growth surface, thus alternating the growth of diamond layers on the opposite surfaces of the diamond multilayer-seed assembly body 40. In an embodiment, the alternating growth of diamond layers should be done in a way so that the thickness of grown diamond layers is about the same. Such alternating growth of diamond layers on the opposite sides of the diamond multilayer-seed assembly body may reduce the stress in the diamond body, because stresses in each two opposite layers of the same thickness may cancel each other. In the steps when the diamond layer (multilayer)-seed body is taken out from the reactor, the body, before it is placed back on the sample holder and into the vapor deposition reactor, it also may be additionally cleaned from all non-diamond material using abovementioned diamond cleaning techniques, for example using chemical cleaning or plasma cleaning

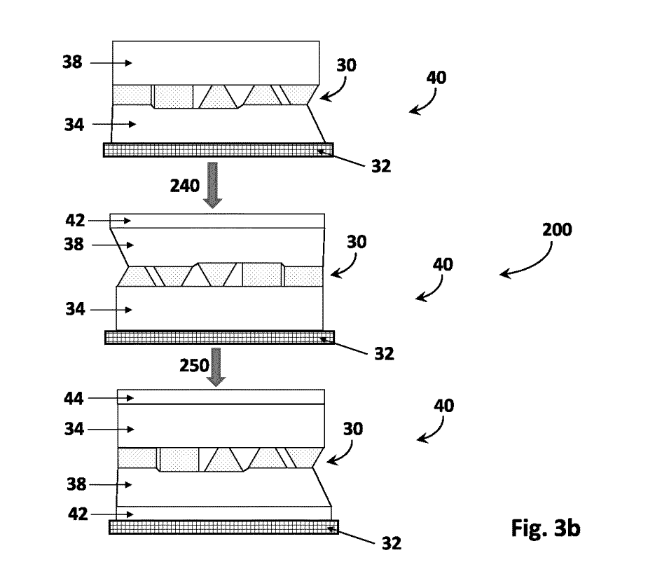

FIG. 4 shows a side schematic view of a cutting of resulting diamond multilayer-seed body 40 along the cutting planes 46 into multiple diamond wafers and a remaining CVD diamond-seed body 50 in a procedure 300. The diamond multilayer-seed body 40 may be cut (or separated) into multilayer diamond wafers by using laser, saw, or lift-off technique employing high energy ion implantation, for example. The diamond wafer, fabricated in such process may comprises the multilayers of vapor deposited diamond without the presence of initial diamond seed material. The remaining CVD diamond-seed body 50 may be reused to make new CVD diamond plates according to the described procedure 200. It is clear that a diamond wafer cut (or separated) from the diamond multilayer-seed body may include only one grown CVD diamond layer or it may include two or more grown CVD diamond layers. It is also clear that any diamond part of interest can be cut (or separated) from the diamond multilayer-seed body, which part may include a multi-crystal diamond region or only a single crystal diamond region.

Multi-crystal diamond bodies grown from assembly of single crystal diamond seeds may be used to make large size diamond wafers suitable for further wafer processing. Processing may include, but not limited to, lapping and polishing to desired thickness, flatness and roughness, patterning by photo-lithography, e-beam lithography or by other patterning techniques. The large size diamond wafer may be used to fabricate individual devices on selected diamond areas of the wafer. For example, selected areas may represent single crystals areas or areas with specific crystallographic orientation. Selected areas on multi-crystal wafer, suitable for device fabrication may be determined by using EBSD, X-ray topography, optical microscopy (birefringence, polarized light, UV-luminescence image, etc.), Raman topography, cathode-luminescence, continuous wave or time-resolved photoluminescence, and other suitable techniques.

### EXAMPLE I

A microwave plasma CVD reactor used for diamond coating was equipped with 2.45 GHz magnetron microwave source, microwave cavity, quartz bell-jar inside which plasma was maintained, water cooled stage inside the bell-jar for sample holder accommodation, gas system for feed-gas supply, and optical pyrometer for surface temperature measurement. Gas pressure inside the bell-jar was 50-400 mBar, and microwave power was 1.5-6 kW. Feed gases were supplied at flow rates of 1000 sccm for hydrogen and 10-100 sccm for methane. Growth conditions were controlled by adjusting the gas pressure inside the bell-jar, microwave power, feed gas flow rates, and the sample holder spatial position inside the plasma. Surface temperature of diamond seeds was controlled by optical pyrometer and kept constant using microwave power or gas pressure feedback.

Several polished (RMS roughness about 5-10 nm), were chemically cleaned and diamond seed plates were placed on a molybdenum support plate in a sample holder sitting on a water-cooled stage inside a CVD reactor in a way that their growth surfaces were directly exposed to the plasma during diamond deposition, facing the plasma ball. A first, about 300 μm thick, diamond layer was grown on the growth surfaces of seed assembly, thus forming a continuous CVD diamond layer over the diamond seeds, bonding diamond seeds together, and making a rigid CVD diamond layer-seed body. Then, the resulting CVD diamond layer-seed body was taken out of the reactor, cleaned from all non-diamond material by etching in the mixture of nitric and sulfuric acids and placed back on the support plate in the sample holder inside a CVD reactor in a way that previous bottom part of the seed assembly, opposite to the first CVD diamond layer, became a new growth surface of the body or a top surface, facing a plasma ball. After the second CVD diamond layer with the thickness of about 300 μm was grown over the new growth surface of the body, the body was taken out from the reactor and cleaned in the acid mixture. The body was used to continue the above mentioned diamond deposition steps alternating the top and bottom surfaces of the body as diamond growth surfaces, and making a thick CVD diamond multilayer-seed body. The alternating growth of diamond layers on the growing surface and bottom parts of the body was done in a way, when the thickness of the consecutive growing surface and bottom grown diamond layers was about the same, approximately 300 μm. The resulting thick CVD diamond multilayer-seed body was cut to form about 1 mm thick diamond wafers.

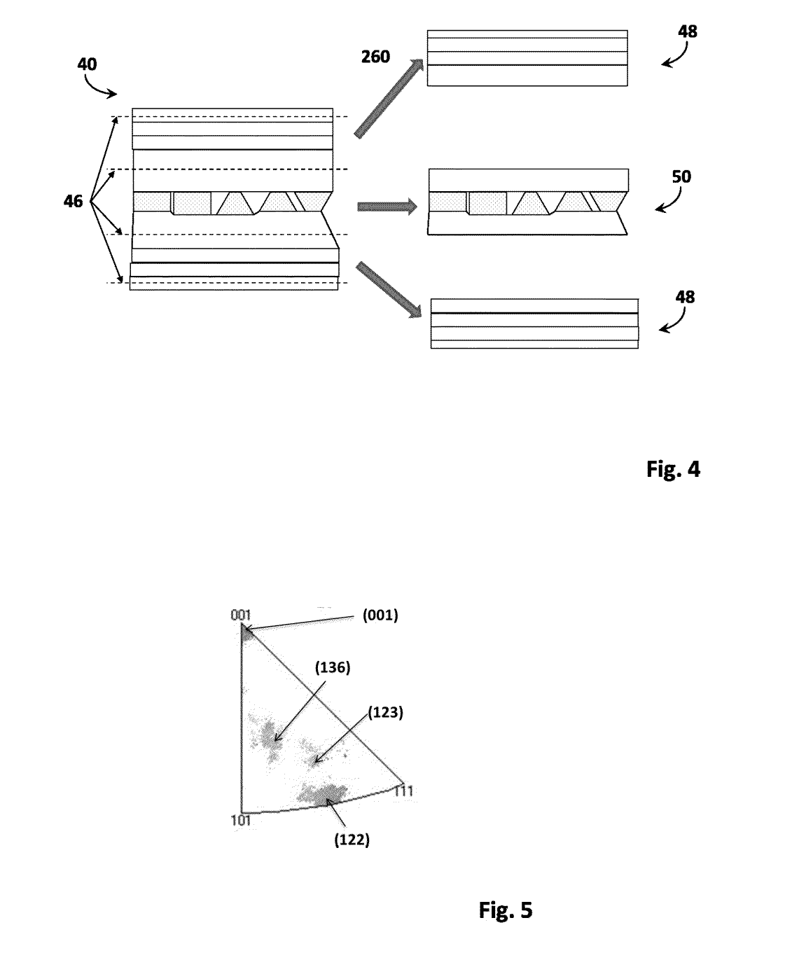

FIG. 5 shows an inverse pole figure corresponding to the electron back scattering diffraction pattern of the exemplary multi-crystal diamond wafer grown from single crystal seed-plates with (100) orientation. Different spots on the polar figure represent different crystallographic orientations expressed in Miller indices. Only four spots, representing four crystallographic orientations are seen on the figure. Thus one (100) spot represents the orientation similar to initial orientation of seed-plates and this (100) orientation accounts for about 80% of the total wafer area and can be called the first single crystal partial area. Other spots on the polar figure represent other crystallographic orientations, i.e. (122), (123), and (136), corresponding to the second, third, and forth single crystal partial areas. Crystallographic orientation of each partial area has some small deviations in orientations, resulting in the finite size of the each spot on the polar figure. Small deviations in each crystallographic orientation may be further reduced by a proper selection of diamond growth conditions.

What is claimed is:

1. A synthetic multi-crystal diamond body, comprising a limited number of single crystal diamond regions having two or more, crystallographic orientations significantly different from each other.

2. The synthetic multi-crystal diamond body of claim 1, wherein crystallographic orientations are not random and related to each other by a geometrical operation.

3. The synthetic multi-crystal diamond body of claim 1, wherein the first single crystal region having a first crystallographic orientation represents less than 100% of the total volume of synthetic multi-crystal diamond body, and the plurality of single crystal regions all having about the same second crystallographic orientation.

4. The synthetic multi-crystal diamond body of claim 1, wherein the first single crystal region having a first crystallographic orientation represents less than 100% of the total volume of synthetic multi-crystal diamond body, the first type plurality of single crystal regions all having about the same second crystallographic orientation, and the second type plurality of single crystal regions all having the about same third crystallographic orientation.

5. The synthetic multi-crystal diamond body of claim 1, wherein the first single crystal region having a first crystallographic orientation represents less than 100% of the total volume of synthetic multi-crystal diamond body, the first type plurality of single crystal regions all having about the same second crystallographic orientation, the second type plurality of single crystal regions all having about the same third crystallographic orientation, and the third type plurality of single crystal regions all having about the same forth crystallographic orientation.

6. The synthetic multi-crystal diamond body of claim 1, wherein the single crystal diamond region is a cubic single crystal diamond.

7. The synthetic multi-crystal diamond body of claim 1, wherein the single crystal diamond region is a hexagonal single crystal diamond.

8. A synthetic multi-crystal diamond wafer, comprising:
a first single crystal partial area; and
a second single crystal partial area, wherein the first single crystal partial area occupies less than about 100% of the total area of synthetic diamond wafer, and the first single crystal partial area has a first crystallographic orientation, and the second single crystal partial area comprises a plurality of single crystals areas all having about the same second crystallographic orientation, which is fixed against the first orientation.

9. A synthetic multi-crystal diamond wafer, comprising:
a first single crystal partial area having the first crystallographic orientation; and two or more of other single crystal partial areas, wherein the first partial area occupies less than about 100% of the total area of synthetic diamond wafer, and each other single crystal partial area has its own crystallographic orientation; and each other single crystal partial area comprises a plurality of single crystals areas all having about the same crystallographic, wherein the crystallographic orientation of each partial area is fixed against the first crystallographic orientation.

10. The synthetic multi-crystal diamond wafer of claim 9, wherein the crystallographic orientation of each other single crystal partial area is different from the first crystallographic orientation by more than about 5°.

11. The synthetic multi-crystal diamond wafer of claim 9, wherein the crystallographic orientation of each other single crystal partial area is different from the first crystallographic orientation by more than about 8°.

12. The synthetic multi-crystal diamond wafer of claim 9, wherein the crystallographic orientation of each other single crystal partial area is different from the first crystallographic orientation by more than about 15°.

13. The synthetic multi-crystal diamond wafer of claim 9, wherein the crystallographic orientation of each other single crystal partial area have small variations in orientation.

14. The synthetic multi-crystal diamond wafer of claim 9, wherein the variations in orientation are less than about 1°.

15. The synthetic multi-crystal diamond wafer of claim 9, wherein the variations in orientation are less than about 5°.

16. The synthetic multi-crystal diamond wafer of claim 9, wherein the variations in orientation are less than about 15°.

17. The synthetic multi-crystal diamond wafer of claim 9, wherein the other single crystal partial areas are within the borders of the first single crystal partial area.

18. The synthetic multi-crystal diamond wafer of claim 9, wherein the other single crystal partial areas are within the borders of the first single crystal partial area and form an ordered array or an ordered pattern.

19. The synthetic multi-crystal diamond wafer of claim 9, wherein the other single crystal partial areas are on borders of the first partial area.

20. The synthetic multi-crystal diamond wafer of claim 9, wherein the other single crystal partial areas represent twinned single crystals, which crystallographic orientations are related to the first crystallographic orientation by a geometrical operation.

21. The synthetic multi-crystal diamond wafer of claim 9, wherein the first single crystal area has a crystallographic orientation (100), and the other single crystal partial areas represent twinned single crystals, which crystallographic orientations are related to the first crystallographic orientation by a geometrical operation

22. A method of making synthetic multi-crystal diamond wafer, comprising:
growing a first diamond layer over a growth surface of a plurality of single crystal diamond seeds on a substrate in a diamond deposition reactor;
removing the substrate with a plurality of seeds and overgrown first diamond layer from the reactor;
separating the plurality of seeds with overgrown diamond layer from the substrate;
turning over the plurality of seeds with overgrown diamond layer, thus making a new diamond growth surface of a plurality of seeds, wherein a new diamond growth surface is opposite to the first grown diamond layer;
growing a second diamond layer on the new diamond growth surface the plurality of single crystal diamond seed in a diamond deposition reactor; and
making diamond wafers from the first or second diamond layers.

23. The method of claim 22, wherein said substrate further comprises at least one seed plate.

24. The method of claim 23 wherein the at least one seed plate comprises single crystal diamond bodies.

25. The method of claim 23 wherein the at least one seed place comprises multi-crystal diamond bodies.

26. The method of claim 22, further comprising:
cleaning the single crystal diamond seeds with overgrown diamond layer to remove non-diamond materials and unwanted growth defects.

27. The method of claim 22, further comprising:
growing a second diamond layer of about the same thickness as a first diamond layer.

28. A method of making synthetic multi-crystal diamond wafer, comprising:
growing a first diamond layer over a growth surface of a plurality of single crystal diamond seeds on a substrate in a diamond deposition reactor;
removing the substrate with a plurality of seeds and overgrown first diamond layer from the reactor;
separating the plurality of seeds with overgrown diamond layer from the substrate;
turning over the plurality of seeds with overgrown diamond layer, thus making a new diamond growth surface of a plurality of seeds, wherein a new diamond growth surface is opposite to first grown diamond layer;
growing a second diamond layer on the new diamond growth surface the plurality of single crystal diamond seed in a diamond deposition reactor;
growing a third diamond layer on the new diamond growth surface, wherein the third diamond layer is opposite to second diamond layer;
growing a forth diamond layer on the new diamond growth surface, which is opposite to third diamond layer, thus making a multilayer diamond seed body;
alternating growth on the opposite sides of multilayer diamond seed body, such as each new consecutive growth surface is an opposite to the previous grown diamond layer; and
making diamond wafers from the multilayer diamond seed body.

29. The method of claim 27, further comprising:
cleaning the multilayer diamond seed body non-diamond materials and unwanted growth defects.

30. The method of claim 27, wherein:
the thickness of each grown diamond layer in multilayer diamond seed body is about the same.

31. The method of claim 27, wherein:
a surface of a plurality of single crystal diamond seeds or a previously grown diamond layer, which is used to grow a new diamond layer, has a pattern or a mask used to change a type of diamond growth or prevent diamond growth on some parts of those surfaces, thus making a total diamond growth surface less than the total surface of single crystal diamond seeds or the total surface of previously grown diamond layer.
